(19) United States
(12) Patent Application Publication
(10) Pub. No.: US 2014/0327012 A1
(43) Pub. Date: Nov. 6, 2014

(54) HEMT TRANSISTORS CONSISTING OF (III-B)-N WIDE BANDGAP SEMICONDUCTORS COMPRISING BORON

(71) Applicants: Abdallah Ougazzaden, Marly (FR); Marie-Antoinette Poisson, Paris (FR); Vinod Ravindran, Limeil-Brevannes (FR); Ali Soltani, Villeneuve D'Ascq (FR); Jean-Claude De Jaeger, Faches Thumesnil (FR)

(72) Inventors: Abdallah Ougazzaden, Marly (FR); Marie-Antoinette Poisson, Paris (FR); Vinod Ravindran, Limeil-Brevannes (FR); Ali Soltani, Villeneuve D'Ascq (FR); Jean-Claude De Jaeger, Faches Thumesnil (FR)

(73) Assignees: THALES, Neuilly-sur-Seine (FR); ALCATEL LUCENT, Paris (FR); CENTRE NATIONAL DE LA RECHERCHE SCIENTIFIQUE - CNRS, Paris (FR); GEORGIA INSTITUTE OF TECHNOLOGY, Atlanta, GA (US); UNIVERSITÉ LILLE I SCIENCES ET TECHNOLOGIES, Villeneuve D'Ascq (FR)

(21) Appl. No.: 14/111,163

(22) PCT Filed: Apr. 16, 2012
(86) PCT No.: PCT/EP2012/056945

§ 371 Date: Dec. 20, 2013

(30) Foreign Application Priority Data
Apr. 14, 2011 (FR) 1101167

(51) Int. Cl. H01L 29/778; H01L 29/205

(52) U.S. Cl. CPC H01L 29/7787; H01L 29/205
USPC 257/76

(57) ABSTRACT

An electronic HEMT transistor structure comprises a heterojunction formed from a first layer, called a buffer layer, of a first wide bandgap semiconductor material, and a second layer of a second wide bandgap semiconductor material, with a bandgap width EG₂ larger than that Eg₁ of the first material, and a two-dimensional electron gas flowing in a channel confined in the first layer under the interface of the heterojunction. The first layer furthermore comprises a layer of a BGaN material under the channel, with an average boron concentration of at least 0.1%, improving the electrical performance of the transistor. Application to microwave power components.

### FIELD OF THE INVENTION

The invention relates to a so-called HEMT (high electron mobility transistor) electronic heterojunction field-effect transistor structure based on heterostructures formed from wide bandgap semiconductor materials, so-called wide-gap materials.

### DESCRIPTION OF THE PRIOR ART

Wide bandgap semiconductor materials are semiconductor materials that have a bandgap width wider than about 2 eV, corresponding to the domain of micron-sized wavelengths, from the near infrared to the deep UV. They typically comprise nitrides of group-III elements, but also diamond and oxides such as zinc oxide.

A group-III nitride is a composition of one or more elements from column III, for example B, Al, Ga or In, alloyed with nitrogen N (group V element). They include binary compositions such as GaN, AlN, BN; or ternary alloys, comprising two group-III elements, such as AlₓGa₁₋ₓN, InₓAl₁₋ₓN, BₓGa₁₋ₓN, BₓAl₁₋ₓN, quaternary alloys comprising 3 group-III elements, BₓAl_{y}Ga_{1-x-y}N, or even quinternary alloys. These alloys are produced by partial substitution of one of the group-III elements with another element of the same column, column III. In these formulae expressing the composition of these materials, x and y are fractions comprised between 0 and 1.

HEMT transistors produced from structures formed from a stack of group-III nitrides, and more generally from wide-gap semiconductor materials, have very advantageous properties for microwave and/or power applications. As is known, these structures use various III-N compositions in stacked layers. Each composition is chosen for its particular electronic properties, for example its effective electron mass, its electron mobility or even the width of its bandgap. Considerations regarding lattice parameters are also taken into account in the choice of the compositions since the lattice parameters determine whether it is possible to grow materials with good structural qualities. Stacking of these materials leads to an electronic structure that is notably characterized by the corresponding energy band diagram. The choice of III-N materials and their compositions used to produce an electronic HEMT transistor structure thus follows from considerations regarding bandgap widths, depending on the desired properties and performance, and lattice matching, required to obtain layers of materials containing low numbers of structural defects.

In particular, regarding the design of HEMT-type field-effect transistors, one known electronic structure, for wide bandgap semiconductor materials, is a heterostructure comprising the superposition of a layer of a first wide bandgap semiconductor material (the barrier zone) on a layer of a second wide bandgap semiconductor material (the active zone), but in which the first material has a wider bandgap than that of the second material.

Since the context of the invention is related to these heterostructures formed from stacks of layers of wide bandgap semiconductor materials, the term “material” is, used alone, understood to mean a semiconductor material with a wide bandgap Eg in the rest of the description.

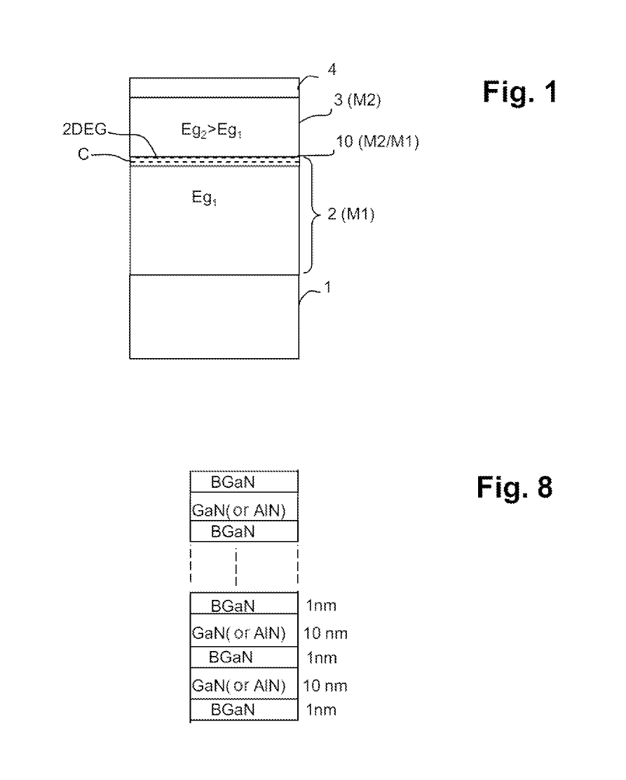

As schematically illustrated in FIG. 1, an electronic HEMT transistor structure essentially consists of three materials:
a substrate 1;
a layer 2 called a buffer layer, of a material M₁ having a bandgap Eg₁; and
a layer 3 called a barrier layer, of a material M₂ having a bandgap Eg₂, where Eg₁ is narrower than Eg₂.

This structure allows a two-dimensional electron gas 2DEG to form and flow in a channel C formed in the material M1 having the narrower bandgap Eg₁, at the interface 10 (or M2/M1 interface) between the two materials M2, M1 of the heterojunction. As illustrated in FIG. 3, this channel corresponds to a confinement of the electrons in a quantum well QW that forms at the interface 10 (or M2/M1 interface) between the two materials M2, M1.

These structures comprising heterojunctions based on stacks of wide bandgap semiconductor materials have particularly promising prospects as regards the production of fast, high-performance HEMTs (high-electron mobility transistors) for microwave power applications (frequencies ranging from 2 GHz to 100 GHz or even higher), and have been the subject of many studies in order to obtain the most advantageous structures, which associate a high two-dimensional electron gas density nₛ with the highest possible carrier mobility, with the aim of obtaining transistors having a high drain current, a necessary condition for effective power amplification.

An important property of the M2/M1 heterojunction, is the good confinement of electrons in the quantum well QW, crucial for the effectiveness of the electron transport of the transistor.

To improve this confinement, it is generally sought to increase the resistivity of the material M1 of the buffer layer, in order to prevent leakage of electrons from the channel C into the substrate, which creates parallel conduction. However, it is difficult to obtain a III-V material that is naturally resistive. In this context, heterostructures have been proposed containing, under the channel layer made of the material M1, a layer of another material with a wider bandgap than that of the material M1, and optionally doped with Fe. These heterostructures have in practice proved to be disappointing, when employed at microwave frequencies, due to a significant increase in the amount of impurities in the structure irreversibly creating traps that are sources of degradation in the performance of the transistor. These sources of degradation are observed in the Ids-Vds characteristic as a degradation in the current.

Another way of improving the confinement of the two-dimensional electron gas in M2/M1 heterojunction structures, with AlGaN/GaN, has been proposed in the publication IEEE Electron Device Letters Vol. 27, No. 1, January 2006, “AlGaN/GaN High Electron Mobility Transistors with InGaN Back-Barriers” by T. Palacios et al. It consists in inserting a thin layer of InGaN under the GaN buffer layer of the conventional AlGaN/GaN HEMT structure. This publication shows that the alloy InGaN, although it has a smaller bandgap than GaN, increases the level of the conduction band of the structure, by virtue of significant electrostatic polarization effects in this type of material. The InGaN layer thus forms an electrostatic barrier that enables more effective confinement of the two-dimensional electron gas in the GaN channel.

However, practical industrial implementation of this solution proves to be difficult on account of the very different temperatures used to grow the various materials of this structure. More precisely, InGaN is grown at a temperature of about 700° C., much lower than the growth temperatures of GaN or AlGaN, which are located at about 1000° C. and 1300° C., respectively.

However, it is not possible to envision lowering the growth temperature of GaN, because this would lead to a reduction in its structural and electronic qualities. Furthermore, incorporating aluminum into AlGaN in any case requires a temperature above 1000° C.

It is also not possible to envision passing, in a few fractions of a second, at the InGaN/GaN interface, from 700° C. to 1000° C.: this would have very disadvantageous effects on the electronic properties of the GaN material and on the structural properties of the InGaN material, there notably being a risk of breakage.

The present invention provides a new way of improving the confinement of the two-dimensional electron gas in the channel.

Regarding the invention, the studies reported in the publication by A. Ougazzaden et al., “Progress on new wide bandgap materials BGaN, BGaAlN and their potential applications”, Proc. Of SPIE Vol. 6479 (2007), conducted on the electrical and structural qualities of thin layers of BGaN, are of interest. It appears from these studies that incorporating as much as 2% boron significantly increases the resistivity and the mobility of charge carriers relative to the material GaN. These two electrical properties are correlated to the very high crystal quality of the structure of the BGaN materials. This publication shows that with a composition containing at least 1% boron, the BGaN layer may be characterized as semi-insulating (>10² ohms·cm) and may therefore be used as a buffer layer in a HEMT structure. As the boron is uniformly incorporated in volume, the thickness of the BGaN layer may be very small or large (from a few tens of nanometers to a few microns). Moreover, BGaN has good characteristics in terms of the lattice match with conventional growth substrates (Al₂O₃, (4H-6H) SiC, Si (111, 100, 110), (single-crystal) GaN, composite substrates, or wide bandgap substrates such as AlN or polycrystalline or single-crystal diamond) which have a good thermal conductivity.

Furthermore, as detailed in the publication “Bandgap bowing in BGaN thin films” by A. Ougazzaden et al., Applied Physics Letters 93, 083118 (2008), ternary BGaN possesses, for low levels of boron incorporation, a narrower bandgap width than that of binary GaN, and, like InGaN, has a significant electronic polarization.

### SUMMARY OF THE INVENTION

Regarding the invention, the inventors thus had the idea of using a semi-insulating BGaN layer as an electrostatic barrier, rather than InGaN under the channel. Advantage is then taken of a double effect, a potential barrier effect promoting confinement of electrons in the potential well, due to the strong electronic polarization of the BGaN layer, and an increase in the resistivity of the structure under the channel, preventing leakage of electrons into the substrate, due to the resistive nature of this layer.

These two effects are obtained for small amounts of boron, 0.1% or more, allowing such a structure to be easily produced with prior-art techniques.

The invention therefore relates to a HEMT transistor structure comprising:
at least one first layer, called a buffer layer, of a first semiconductor material having a wide bandgap Eg₁, and a second layer of a second semiconductor material having a wide bandgap Egg, with a bandgap width Eg_{g} larger than Eg₁, and
a two-dimensional electron gas that flows in a channel confined in the first layer at the interface between the first and second layers.

According to the invention, a semi-insulating BGaN material with an average boron concentration of at least 0.1% is inserted in the buffer layer, in the form of at least one layer under the channel layer, modifying the energy band diagram by creating an electrostatic potential barrier promoting confinement of the two-dimensional electron gas.

This BGaN layer may take the form of a layer of BGaN, in the buffer layer, under the channel, which has a uniform boron concentration throughout its thickness; or which has a concentration that is graded or stepped in the thickness, starting from a zero concentration and increasing with thickness toward the channel.

When the buffer layer is a layer of binary GaN, or of an alloy of GaN, clusters of BGaN may be directly produced in the buffer layer.

This confinement layer may even take the form of a superlattice of very thin layers in which BGaN layers alternate in succession with GaN layers or with AlN layers.

The invention also relates to the use of other BGaN layers for the purpose of improving the electronic structure of the HEMT transistor.

In a first improvement, the structure comprises a BGaN layer as a nucleation layer, allowing the structural quality of the second layer obtained by growing material from this nucleation layer to be improved. Here it is the structural qualities of the BGaN that are exploited.

In another improvement, the structure comprises a layer of BGaN or of BN as a surface passivation layer, in order to minimize the influence of possible surface traps. Here it is the resistive properties of the BGaN or the BN that are advantageously exploited.

Other advantages and features of the invention will be detailed in the description of a number of embodiments of the invention, and with reference to the appended drawings, in which:

FIG. 1 schematically illustrates an electronic structure for a prior-art HEMT transistor;

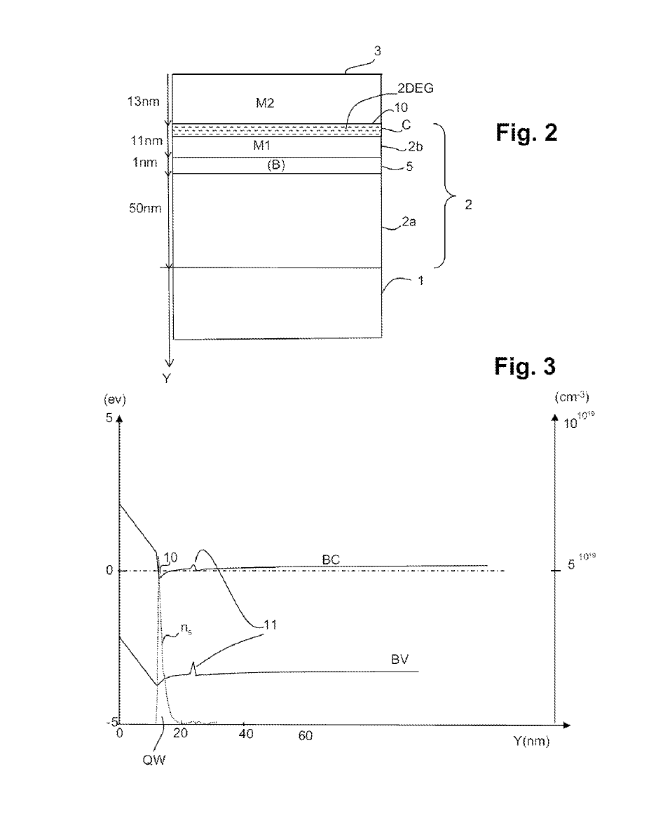

FIGS. 2 and 3 illustrate an electronic structure for a HEMT transistor in a first embodiment of the invention and the corresponding energy band diagram, respectively, with the use of a thin layer of BGaN and formation of an electrostatic barrier;

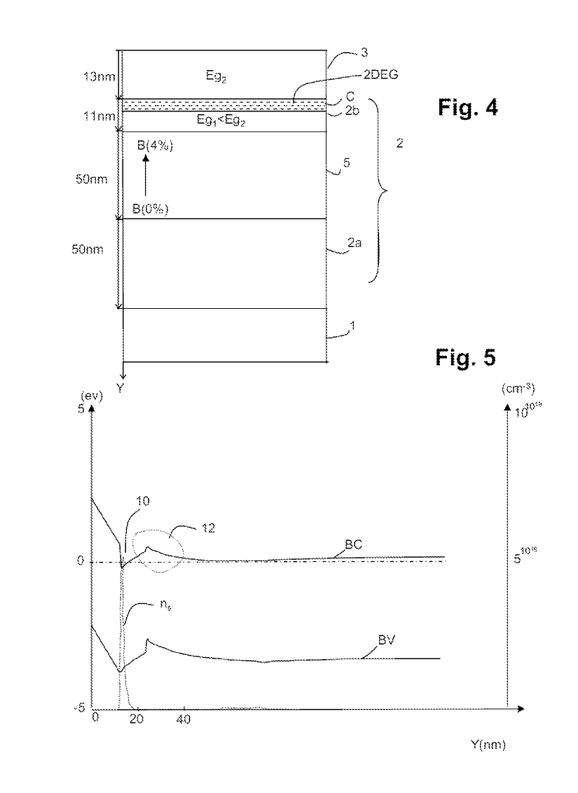

FIGS. 4 and 5 illustrate an electronic structure for a HEMT transistor in a second embodiment of the invention and the corresponding energy band diagram, respectively, with the use of a layer having a graded boron composition and the formation of an electrostatic barrier the peak of which is located at the gas-side end;

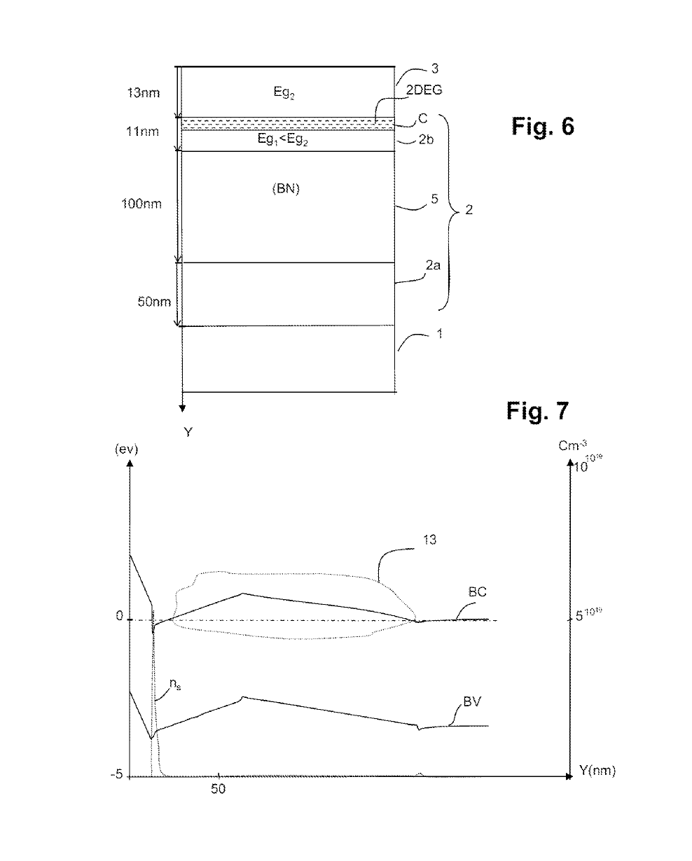

FIGS. 6 and 7 illustrate an electronic structure for a HEMT transistor in a third embodiment of the invention and the corresponding energy band diagram, respectively, with the use of a thick BGaN layer and the formation of a wider electrostatic barrier;

FIG. 8 shows a superlattice type BGaN layer structure that may be used in the structures illustrated in FIGS. 2, 4 and 6;

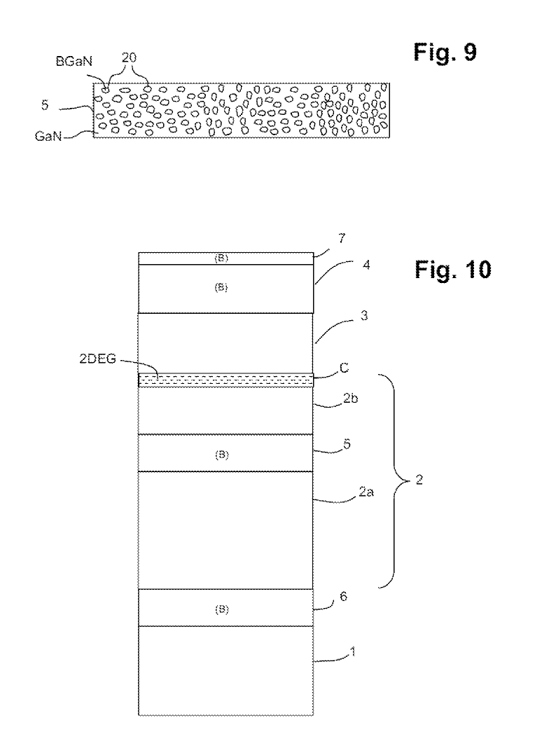

FIG. 9 illustrates another BGaN layer structure of the type comprising volume-localized incorporations;

FIG. 10 illustrates a structure comprising improvements according to the invention;

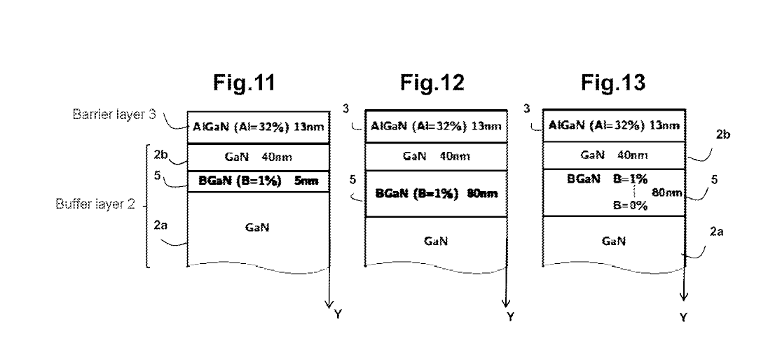

FIGS. 11 to 13 illustrate three practical examples of a AlGaN/GaN structure with insertion of a layer of a BGaN material according to the invention, respectively a thin layer having a uniform boron concentration, a thick layer having a uniform boron concentration, and a thick layer with a boron concentration gradient;

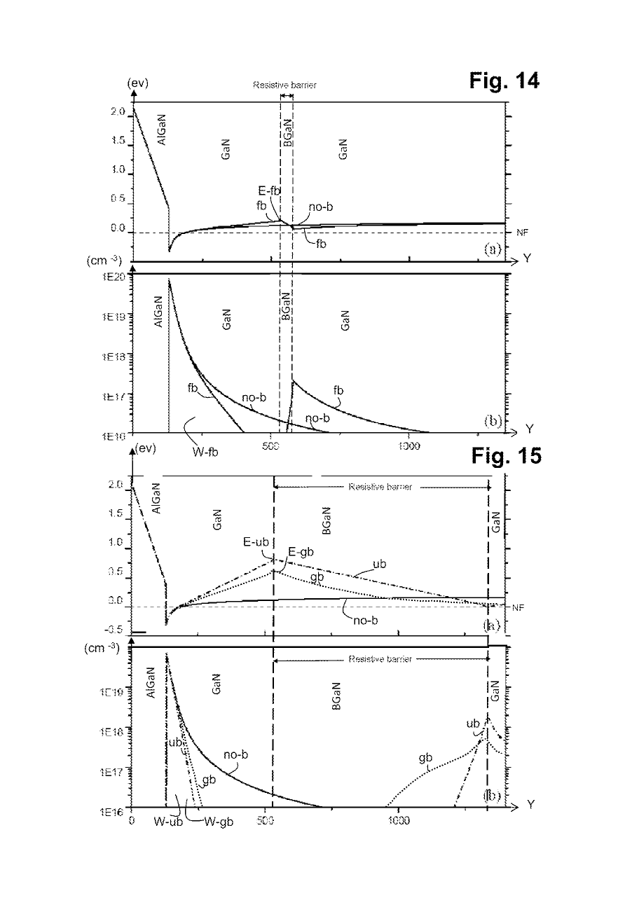

FIG. 14 illustrates curves obtained by simulating the thin-BGaN-layer-containing structure in the FIG. 11, with, in an upper window (a), along the axis Y, corresponding to the thickness of the structure, starting from the surface and proceeding toward the substrate, the curve of the energy level of the conduction band of the structure, and, in the lower window (b), the curve of the carrier concentration in the structure along the axis Y;

FIG. 15 illustrates the same curves of conduction band energy level and of carrier concentration, but obtained by simulating the thick-BGaN-layer structure with uniform boron concentration illustrated in FIG. 12, and that with the gradually varying boron concentration illustrated in FIG. 13;

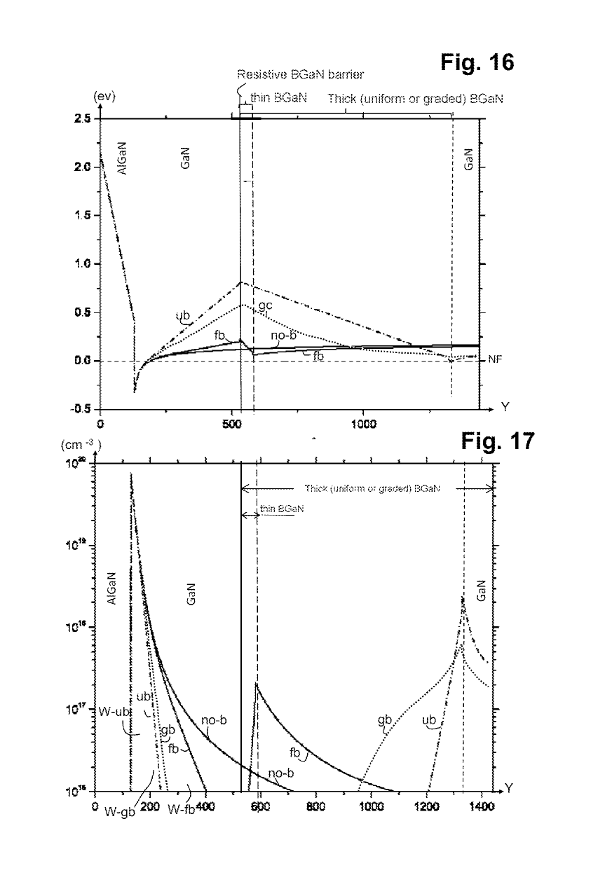

FIG. 16 shows in the same graph the curves of the energy levels of the conduction bands of the three structures in FIGS. 11, 12 and 13; and

FIG. 17 shows in the same graph the carrier concentration curves of each of the three structures in FIGS. 11 to 13.

### DETAILED DESCRIPTION

By way of introduction it will be noted that the figures illustrating the stacks of layers of the electronic structure are not drawn to scale. Notably, the thicknesses shown are not proportional. Moreover, for the sake of simplicity with respect to references, elements common to all the structures have been given the same references.

The invention will in particular be described with regard to a nonlimiting example application to an electronic structure for a HEMT transistor based on the III-nitrides, and more particularly on an AlGaN/GaN heterojunction. AlGaN is the material M2 of the barrier layer having a bandgap Egg that is wider than that Eg₁ of the first material M1 of the buffer layer, which is GaN.

According to the invention, the structure comprises a BGaN layer in the buffer layer, under the channel.

A first example of an electronic structure according to the invention is illustrated in FIG. 2. It comprises the following stack of layers, in the order they are grown (stacked):
a semi-insulating substrate 1 specific to the material system, i.e. lattice matched or partially lattice matched to the materials forming the heterostructure and obtained by crystal growth from this substrate. Various types of substrate are commonly used: low-cost substrates such as Si with (111), (100) or (110) crystal orientation, single-crystal Al₂O₃, or (4H or 6H) SiC the cost of which is very high. Composite substrates such as SopSic (silicon/oxide/polycrystalline SiC), SiCopSiC (single-crystal SiC/oxide/polycrystalline SiC), or polycrystalline diamond; ZnO substrates, SiC substrates (to a lesser extent) and single-crystal diamond substrates are materials that have good properties with regard to heat dissipation. Mention may also be made of so-called “pseudo-substrates” of GaN, AlN, or ZnO or even flexible substrates such as substrates made of Kapton, or PTFE (polytetrafluoroethylene) to which the epimaterial is transferred. This list of substrates is not intended to be exhaustive. The choice of the substrate is closely related to the specifications of the application, and takes into account cost, the expected performance, and the lattice parameter of the material layers of the envisioned heterostructure.
   It will be noted that the substrate may be a temporary substrate used to produce the epilayers, via material growth. It may then be removed by any known technique, the structure thus detached from its growth substrate being transferred to another substrate, for example a glass substrate, a flexible substrate, or a substrate having a good thermal conductivity. An electronic structure may thus temporarily be without substrate, or the final substrate, in the component, might not be the growth substrate.
a buffer layer 2 (also referred to as a template layer in the literature) of a nitride, in this example GaN, generally composed of a first GaN layer 2a that serves, as is known, as a high-crystal-quality base material for crystal growth of a second GaN layer 2b having excellent structural qualities. Specifically, the two-dimensional electron gas will form in this layer near the heterojunction.
a barrier layer 3 formed from a material having a wider bandgap. In the example, this layer is a wide bandgap AlGaN or InAlN composition such as Al_{0.32}Ga_{0.68}N (x=0.32). It could also be a layer of AlN. In practice, the barrier layer may comprise a plurality of elementary layers (not illustrated), notably a doped layer called a donor layer, which provides free electrons that participate to form the two-dimensional electron gas in the buffer layer, and an unintentionally doped layer, called a spacer layer, between the doped layer and the buffer layer, which layer enhances the mobility of the electrons in the transport channel of the two-dimensional electron gas. It is not envisioned to dope nitride structures since doping is often pointless, the electrons essentially coming from the surface via a piezoelectric polarization effect and from spontaneous generation.
a passivation layer 4 (also called a “cap layer” in the literature) as illustrated in FIG. 1 may be provided (not illustrated in FIG. 2), this layer being formed by a material having a narrower bandgap width than the material M2 of the barrier layer, and being highly n-doped, in order to allow the source and drain ohmic contacts (not shown) of the HEMT transistor to be produced. It is for example a layer of highly n-doped GaN. The passivation layer will be infrequently used when the structural quality of the layer is high. It above all makes it possible to prevent oxidation of the aluminum in the barrier layer. If the passivation is present, doping will possibly be carried out under the contacts exclusively.

According to the invention, the structure furthermore comprises a layer 5 of BGaN in the buffer layer 2, under the channel C.

In the example illustrated a GaN layer 2a, containing the channel C, obtained by regrowth of a GaN layer 2b, as explained above, the BGaN layer is inserted between the GaN layer 2a and the GaN layer 2b.

Throughout the description, the expression “BGaN layer” or “BGaN material” is understood to encompass both ternary BGaN and alloys of higher orders, i.e. it includes quaternary BlnGaN, BAlGaN, or quinternary BAlInGaN. This observation also applies to the other materials of the structure.

In this first example structure, the BGaN is a thin layer with a thickness of about 1 nanometer and a uniform boron concentration. The BGaN material is a ternary semiconductor, with a boron concentration of about 1 to 4%, written: B_{0.01}Ga_{0.96}N and B_{0.04}Ga_{0.96}N, respectively.

The energy band diagram obtained by modeling, for this structure, is illustrated in FIG. 3. It shows the energy levels, in electron volts, of the valence band BV and the conduction band BC obtained (left-hand vertical axis), and the distribution of the electron density in the structure (in cm⁻³) (right-hand vertical axis), with height in the structure along the transverse axis Y (nanometers). The origin Y=0 corresponds to the surface of the layer 3 (FIG. 2). The diagram shows the formation of the triangular potential well QW at the interface 10 between the two materials AlGaN (M2) and GaN (M1). The valence and conduction energy band curves exhibit a very marked decrease followed by a very marked increase at the location of the interface 10, corresponding to the formation of the potential well QW. This potential well confines the two-dimensional electron gas 2DEG at the interface, as illustrated by the electron-density distribution curve shown by the dotted line in the figure. The electron density nₛ is maximum in this well. This is the principle of the 2D gas associated with the heterojunction.

The presence of the BGaN layer 5 under the channel C of the structure according to the invention, furthermore results, in the band diagram, in the creation of two energy peaks 11 that corresponds to the valence and conduction bands of the BGaN: these peaks form an electrostatic barrier that makes the leakage of electrons out of the well more difficult. The confinement of the electrons in the potential well QW at the interface 10 is thus improved. This barrier is in this example quite narrow, corresponding to the small thickness, 1 nm in the example, of the BGaN layer 5.

The BGaN layer has another effect, that of increasing the resistivity of the structure under the channel, preventing leakage of electrons into the substrate.

Thus, the BGaN layer has two effects that each tend to improve the confinement of the two-dimensional electron gas: on the one hand because the BGaN layer improves the energy band diagram; and on the other hand because the BGaN layer increases the resistivity of the structure under the channel, preventing leakage of electrons from the channel into the substrate.

FIGS. 4 and 6 show two other example structures according to the invention, and FIGS. 5 and 7, their respective energy band diagrams. These figures show that depending on concentration and the thickness of the BGaN layer, it is possible to increase and/or widen the electrostatic barrier created by the BGaN layer, improving the confinement of the two-dimensional electron gas.

In FIG. 4, the BGaN layer is thicker, about 50 nm in thickness (compared to 1 nm in the example illustrated in FIG. 2), but with a boron concentration that is sloped or graded in steps: the boron concentration is zero at the interface with the layer 2b, and increases toward the channel (in the layer 2a), for example up to 4%. FIG. 5, the corresponding band diagram, shows an accentuated and wider electrostatic barrier 12 effect. The use of a boron concentration gradient over a larger layer thickness thus allows a more distinctive electrostatic barrier to be formed, which barrier will further limit movement of electrons out of the potential well.

In FIG. 6, the BGaN layer is even thicker, about 100 nm in thickness, but has a very low boron concentration, about 1% (B_{0.01} Ga_{0.99}N). FIG. 7, the corresponding band diagram, shows that an even wider electrostatic barrier 13 is obtained, because of the large thickness of the layer. This structure is very advantageous because such a low-boron-concentration layer is easy to produce. Furthermore, even with these low boron concentrations, electrostatic-barrier and resistivity-increase effects are still observed in the structure under the channel.

In practice, the BGaN layers used according to the invention are characterized by an average boron concentration of at least 0.1%.

The layer will preferably be from about 1 nanometer to several hundred nanometers in thickness.

The invention, which was just described for an example AlGaN/GaN heterojunction structure, thus provides for insertion of a BGaN layer into the buffer layer, under the channel, in order to obtain a two-fold beneficial modification of the band diagram with formation of an electrostatic barrier that increases in width as the BGaN layer increases in width, and an increase in the resistivity of the structure under the channel.

The invention notably, or more generally, applies to all the heterojunction structures obtained with layers chosen from the binary III-nitrides, i.e. from AlN, GaN, InN, BN, and the ternary, quaternary or quinternary semiconductors obtained from these binary semiconductors. It more generally applies to HEMT transistor structures based on wide bandgap semiconductor materials, comprising the III-V semiconductors materials, diamond or zinc oxide (and any other material mentioned above). The first material M1 will preferably be a binary III-nitride, typically AlN, or a ternary or quaternary alloy formed from a binary semiconductor from the following list: AlN, GaN, InN, BN. This may also be diamond or a zinc oxide ZnO layer. The second material M2 may be a III-nitride, and notably a binary semiconductor (AlN, GaN, InN, BN), or a ternary or quaternary alloy formed from a binary semiconductor from the list AlN, GaN, InN, BN.

In practice, the BGaN layer on the buffer layer 2a may be obtained in various ways, using a range of currently available techniques for growing this material, i.e. typically: molecular beam epitaxy (MBE) or vapor phase techniques; metal organic (MOCVD) or hybrid (HVPE) techniques; techniques for implanting boron in a GaN layer, and diffusion techniques, with deposition and annealing phases. These techniques furthermore allow, as is known, the BGaN layer to be formed in various ways. Notably:
the BGaN layer may be formed with a uniform homogenous boron volume concentration, as in the example illustrated in FIG. 1.
the BGaN layer may also be formed with a sloped concentration or one graded in steps, starting from 0 and increasing, as it approaches the channel, to a higher concentration, for example 4%, as schematically illustrated in FIG. 4.
the BGaN layer may also take the form of a superlattice formed from an alternation of very thin layers, for example layers of BGaN and GaN alternating, as schematically illustrated in the structure in FIG. 8, over a set structure thickness, in the example 50 nm, in order to achieve an equivalent average concentration. An alternation of BGaN and AlN layers may also be envisioned.
the BGaN layer may even take the form of a GaN or BGaN layer with volume-localized incorporations of BGaN containing higher concentrations of boron, forming small volumes or clusters 20 in the surrounding buffer layer, as schematically illustrated in FIG. 9. The thickness of the surrounding layer and the density of the clusters and the respective concentrations of the surrounding layer and of the clusters 20 are set in order to obtain the average concentration sought. When the buffer layer 2a is a GaN layer (made of GaN or an alloy of GaN with other column-III elements), these clusters may be produced directly in the buffer layer. The surrounding layer in which the BGaN clusters are produced may thus be a layer inserted in the buffer layer 2 of the structure.

In the invention, it is furthermore proposed to improve the HEMT transistor structure described above using the electrical, notably resistive, properties and structural qualities of BGaN layers in other levels of the structure, further improving the electrical performance of the HEMT transistor.

FIG. 10 illustrates these improvements for an example AlGaN/GaN heterojunction structure.

A first improvement consists in using a BGaN layer having a low boron concentration at the interface between the substrate and the buffer layer, by way of a nucleation layer 6 for the growth of the buffer layer. This BGaN layer deposited on the substrate 1, with a thickness possibly ranging up to 2 μm, then acts as a dislocation filter favorable for obtaining a buffer layer 2 having very good structural qualities. In this case, this nucleation layer 6 will preferably be produced using the cluster technique presented in FIG. 9.

A second improvement consists in using a BGaN layer having a low boron concentration to produce the surface passivation layer 4, for its resistive properties, the passivation layer having the function of passivating possible surface traps on the surface of the structure. In this case, this BGaN passivation layer 4 will preferably be produced with a uniform boron concentration, or consist of a superlattice. As an alternative to BGaN, BN, which has equally advantageous resistive properties, may also be used for this surface passivation layer 4.

A third improvement consists in using a BGaN or BN layer to promote the dissipation of heat from the HEMT structure. Specifically, promoting heat dissipation from the structure is an important aspect in all power applications. With this in mind, BGaN and BN are good thermal conductors, and notably they are better thermal conductors than SiN or SiO₂, which are currently used for the layer 4 for passivating the structure.

It is thus proposed, advantageously, to produce a BGaN or BN layer on the surface of the structure, with the aim of reducing the thermal bridge with an optional radiator placed on the structure. As, as was seen above, such a BGaN or BN layer can also be used as a passivation layer, two variant embodiments may be envisioned:
a BGaN or BN layer may be produced on the surface of the structure in order to form the passivation layer 4, and thus both passivate the structure and reduce the thermal bridge between the active zone beneath it and an optional radiator placed on it.
a BGaN or BN layer may be produced on a passivation layer 4, for example a SiN passivation layer. A passivation layer 4/BGaN or BN layer 7 superposition is then obtained as illustrated in FIG. 10.

It is also possible to envision cooling the structure from below, and to produce a BGaN or BN layer under the buffer layer 6, such as illustrated in FIG. 10. It is then necessary to transfer the structure to a suitable substrate 1 (e.g.: SiC, diamond, with a thermally compatible interface and/or bond) to improve bulk thermal conductivity and total thermal resistance. The layer 6 may then serve as a nucleation layer in the fabrication process of the structure, and then as a layer promoting dissipation of heat after transfer to a suitable substrate.

The various improvements described may be used separately or in combination, depending on the qualities and performance sought for the HEMT transistor produced with this structure.

FIGS. 11 to 17 show the results of simulations obtained for three structures formed according to the invention, and illustrate the effect of charge-carrier confinement at the barrier layer/buffer layer interface of a HEMT transistor structure with a BGaN layer inserted in the buffer layer, according to the invention, and the effect of the resistivity increase under the channel. They demonstrate that these effects are noteworthy even with a low boron concentration, which in the example of the simulation is 1%, and the notable variation of these effects with the thickness of the inserted BGaN layer.

More precisely, the three HEMT structures simulated are AlGaN/GaN structures comprising a BGaN material inserted according to the invention. In these structures, the barrier layer 3 is a layer of AlGaN chosen to have an Al concentration of 32% and a thickness of 13 nanometers. The BGaN layer 5 is inserted according to the invention in the GaN buffer layer, so that part 2b of the buffer layer is located between the AlGaN barrier layer 3 and the BGaN layer 5. In the example, this buffer-layer part 2b is 40 nanometers in thickness.

In the structure schematically shown in FIG. 11, the BGaN layer 5 is thin, with a thickness of 5 nanometers, and has a uniform boron concentration of 1% in the example.

In the structures in FIGS. 12 and 13, the BGaN layer 5 is thicker, having a thickness of 80 nanometers (1 nm=10⁻⁹m). The boron concentration of the structure in FIG. 12 is uniform and equal to 1%. In the structure in FIG. 13, it has a concentration gradient and ranges from 0% at the boundary with that part 2a of the buffer layer under the BGaN layer, as shown in the figure where the barrier layer 3 is located on top of the buffer layer, to 1% at the boundary with that part 2b of the buffer layer on top of the BGaN layer. The buffer “layer” according to the invention is thus formed, in the structure, by the sequence GaN 2b/BGaN 5/GaN 2a.

FIG. 14 illustrates energy level curves for the conduction band, and carrier concentration as a function of thickness Y, for the structure in FIG. 11, starting from the barrier layer 3 and progressing toward the buffer layer, thickness being represented by the axis Y. Thickness is given in angstroms (1 Å=10⁻¹⁰ m). In the figure (as in the following FIGS. 15 to 17) the position of the layers has been indicated in succession according to their position in the structure along the axis Y, i.e.: AlGaN/GaN/BGaN/GaN. The Fermi level, denoted NF, is also shown. The upper window (a) of FIG. 14 illustrates the energy level curve (in electron volts “eV”) of the structure, referenced by the symbol fb. It also shows the curve that would be obtained for the same structure but without the BGaN layer according to the invention (all else being equal): this curve is referenced by the symbol no-b. The lower window (b) illustrates curves of carrier concentration (in cm⁻³): that referenced by the symbol fb corresponding to the structure in FIG. 11, and that referenced by the symbol no-b corresponding to the same structure but without the BGaN layer 5. FIG. 15 shows corresponding curves, but obtained:
for the structure in FIG. 12, with a thick BGaN layer, 80 nm in thickness in the example compared to 5 nm in the structure in FIG. 11, and a uniform boron concentration: the curves corresponding to this structure are referenced by the symbol ub;
for the structure in FIG. 13, also with a thick BGaN layer, 80 nm in thickness in the example, but with a graded boron concentration: the curves corresponding to this structure are referenced by the symbol gb.

The curves referenced by the symbol no-b, corresponding to an identical structure but without a BGaN layer, are also shown.

FIG. 16 allows the various conduction band energy level curves of all these structures to be compared, and similarly FIG. 17 allows the various carrier concentration curves of all these structures, and the effects induced by the BGaN layer inserted according to the invention, to be compared: improvement of the confinement via the electrostatic barrier effect, and reduction in leakage of electrons into the substrate via the resistive barrier effect.

These various figures clearly show the influence of boron concentration and of the thickness of the BGaN layer inserted according to the invention. Thus, the amplitude of the energy peak in the conduction band, at the GaN/BGaN interface (layer 2b/layer 5), referenced E-fb for the structure in FIG. 11, E-ub for the structure in FIG. 12, and E-gb for the structure in FIG. 13, respectively, and the width of the electrostatic barrier induced, increases as the thickness of the BGaN layer increases. For equal thickness, the amplitude of the peak and the electrostatic barrier are greater for a uniform concentration of 1% boron (curve “ub” and peak E-ub) than for a 0%-1% concentration gradient (curve “gb”, peak E-gb). The width of the base of the triangular potential well at the AlGaN/GaN interface, referenced W-fb, W-ub and W-gb, also depends on boron concentration and the thickness of the BGaN layer, as shown very well by FIG. 17: the narrower the curve ub, the wider the curve fb. These curves are to be compared with the explanations given above in the description of the invention with regard to FIG. 3.

The invention described above makes it possible to produce very high-performance HEMT transistors having improved electrical properties.

1. An electronic HEMT transistor structure, comprising:
at least one first layer, being a buffer layer, of a first semiconductor material having a wide bandgap Eg₁, and a second layer of a second semiconductor material having a wide bandgap Eg₂, with a bandgap width Eg₂ larger than Eg₁, and
a two-dimensional electron gas that flows in a channel confined in the first layer at the interface between the first and second layers,
wherein a BGaN material with an average boron concentration of at least 0.1% is inserted in the buffer layer, in the form of at least one layer under the channel, modifying the energy band diagram by creating an electrostatic potential barrier promoting confinement of the two-dimensional electron gas.

2. The electronic structure as claimed in claim 1, in which the BGaN layer under the channel has a thickness comprised between 1 nanometer and one hundred nanometers.

3. The electronic structure as claimed in claim 1, further comprising a BGaN layer, at the interface between the buffer layer and a substrate of the structure, by way of a nucleation layer, forming a dislocation filter during growth of the buffer layer.

4. The electronic structure as claimed in claim 1, further comprising a BGaN or BN layer at the interface between the buffer layer and a substrate of the structure, in order to promote heat dissipation from the HEMT transistor.

5. The electronic structure as claimed in claim 1, further comprising a BGaN or BN layer on the surface of the structure, on the barrier layer, said BGaN or BN layer serving as a surface passivation layer, and enabling heat dissipation via the top of the structure.

6. The electronic structure as claimed in claim 1, further comprising a passivation layer formed on the barrier layer, and a BGaN or BN layer on the passivation layer, enabling heat dissipation via the top of the structure.

7. The electronic structure as claimed in claim 1, in which the BGaN layer under the channel has a uniform boron volume concentration.

8. The electronic structure as claimed in claim 1, in which the BGaN layer under the channel has a graded or stepped boron concentration, increasing in the direction of the channel.

9. The electronic structure as claimed in claim 1, in which the BGaN layer under the channel is a superlattice in which BGaN layers alternate with GaN layers or with AlN layers.

10. The electronic structure as claimed in claim 1, in which the BGaN layer under the channel is formed from a surrounding GaN or BGaN layer, locally incorporating BGaN in its volume in various zones called being clusters, having a boron content higher than that of the surrounding layer.

11. The electronic structure as claimed in claim 3, in which the BGaN layer employed as a nucleation layer, at the interface between the buffer layer and the substrate of the structure, locally incorporates BGaN in its volume in various zones called clusters.

12. The electronic structure as claimed in claim 1, in which said first and second materials are III-nitrides.

13. The electronic structure as claimed in claim 12, in which the first material is binary GaN, or an alloy of this binary semiconductor with one or more group III or group V elements, and the second material is ternary AlGaN alloy or an alloy of this ternary semiconductor with group III or group V elements.

14. An electronic device comprising at least one HEMT transistor with an electronic structure as claimed in claim 1.
